(19) United States
(12) Patent Application Publication
(10) Pub. No.: US 2015/0114616 A1
(43) Pub. Date: Apr. 30, 2015

(54) HEAT DISSIPATION SYSTEM

(71) Applicant: HON HAI PRECISION INDUSTRY CO., LTD., New Taipei (TW)

(72) Inventor: TAI-WEI LIN, New Taipei (TW)

(73) Assignee: HON HAI PRECISION INDUSTRY CO., LTD., New Taipei (TW)

(21) Appl. No.: 14/083,461

(22) Filed: Nov. 19, 2013

(30) Foreign Application Priority Data
Oct. 29, 2013 (TW) 102139033

(51) Int. Cl. H05K 7/20; F28F 27/02

(52) U.S. Cl. CPC H05K 7/20781; F28F 27/02; H05K 7/20836
USPC 165/287; 165/96

(57) ABSTRACT

A heat dissipation system for cooling a cabinet server with an outlet and an inlet includes an outlet pipe connected to the outlet, an inlet pipe connected to the inlet, a pump apparatus located between the outlet pipe and the inlet pipe, a first heat dissipation apparatus, a second heat dissipation apparatus, and a valve. The first and second heat dissipation apparatus are connected between the outlet pipe and the pump apparatus in parallel. The first valve apparatus includes a first end connected to the outlet pipe, a second end connected to the first heat dissipation apparatus, and a third end connected to the second heat dissipation apparatus. The first end of the valve is operable to be connected to either the second end or the third end.

### BACKGROUND

1. Technical Field

The present disclosure relates to a heat dissipation system for a liquid cooled cabinet server.

2. Description of Related Art

A liquid cooling device for a container data center usually includes a heat dissipation apparatus, a pump apparatus, and a water tank. However, because a large number of high performance severs are installed in the container data center, the heat generated by the servers during normal operation is commensurately increased. If the generated heat cannot be quickly dissipated from the container data center, the servers will be overheated, and eventually the performance and stability of the servers will be affected.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic view of a first embodiment of a heat dissipation system.

FIG. 2 is a block diagram of the heat dissipation system of FIG. 1.

FIG. 3 is similar to FIG. 1, but shows the heat dissipation system in a first state of use.

FIG. 4 is similar to FIG. 1, but shows the heat dissipation system in a second state of use.

FIG. 5 is a schematic view of a second embodiment of a heat dissipation system.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

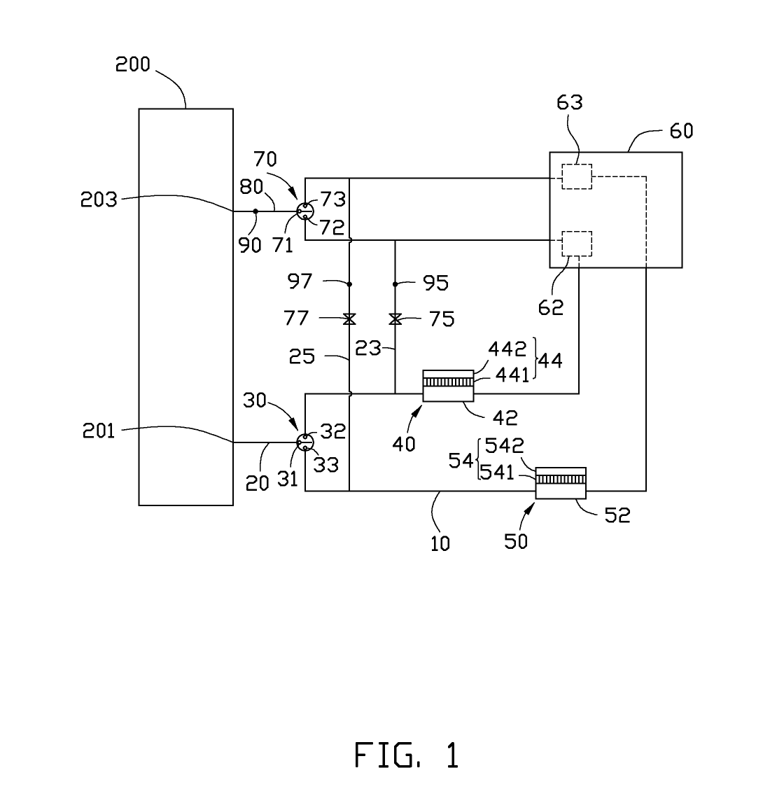

FIG. 1 shows a first embodiment of a heat dissipation system for dissipating a liquid cooling cabinet server 200. The liquid cooling cabinet server 200 defines an outlet 201 and an inlet 203. The heat dissipation system includes an outlet pipe 20, a first valve apparatus 30, a first heat dissipation apparatus 40, a second heat dissipation apparatus 50, a pump apparatus 60, a second valve apparatus 70, an inlet pipe 80, a first temperature sensor 90, a second temperature sensor 95, a third temperature sensor 97, a third valve 75, a fourth valve 77, a first branch pipe 23, a second branch pipe 25, a plurality of connecting pipes 10, and a controller 100. The pump apparatus 60 includes a first pump 62 and a second pump 63.

In the embodiment, the first valve apparatus 30 is a three way valve, the first valve apparatus 30 includes a first end 31, a second end 32, and a third end 33. A first end of the outlet pipe 20 is connected to the outlet 201, and a second end of the outlet pipe 20 is connected to the first end 31. The first heat dissipation apparatus 40 includes a first water tank 42 and a first heat dissipation assembly 44 mounted to the first water tank 42. The second heat dissipation apparatus 50 includes a second water tank 52 and a second heat dissipation assembly 54 mounted to the second water tank 52. The first water tank 42 is connected between the second end 32 of the first valve apparatus 30 and the first pump 62 through the connecting pipes 10. The second water tank 52 is connected between the third end 33 of the first valve apparatus 30 and the second pump 63 through the connecting pipes 10. The first heat dissipation assembly 44 includes a heat sink 441 attached on the first water tank 42 and a fan 442 installed to the heat sink 441. In another embodiment, the first heat dissipation assembly 44 may be a condenser.

In the illustrated embodiment, the second valve apparatus 70 is a three way valve, second valve apparatus and includes a first end 71, a second end 72, and a third end 73. A first end of the inlet pipe 80 is connected to the inlet 203, and a second end of the inlet pipe 80 is connected to the first end 71 of the second valve apparatus 70. The second end 72 of the second valve apparatus 70 is connected to the first pump 62 through the connecting pipe 10, and the third end 73 of the second valve apparatus 70 is connected to the second pump 63 through the connecting pipe 10. The first temperature sensor 90 is installed to the inlet pipe 80. The second heat dissipation assembly 54 includes a heat sink 541 attached on the second water tank 52 and a fan 542 installed to the heat sink 541. In another embodiment, the second heat dissipating assembly 54 may be a condenser.

An end of the first branch pipe 23 is connected to a point of the connecting pipe 10 between the second end 72 of the second valve apparatus 70 and the first pump 62, and an opposite end of the first branch pipe 23 is connected to a point of the connecting pipe 10 between the second end 32 of the first valve apparatus 30 and the first heat dissipation apparatus 40. The third valve 75 is installed to the first branch pipe 23. The second temperature sensor 95 is installed to the first branch pipe 23, and located between the first pump 62 and the third valve 75.

An end of the second branch pipe 25 is connected to a point of the connecting pipe 10 between the third end 73 of the second valve apparatus 70 and the second pump 63, and an opposite end of the second branch pipe 25 is connected to a point of the connecting pipe 10 between the third end 33 of the first valve apparatus 30 and the second heat dissipation apparatus 50. The fourth valve 77 is installed to the second branch pipe 25. The third temperature sensor 97 is installed to the second branch pipe 25, and located between the second pump 63 and the fourth valve 77.

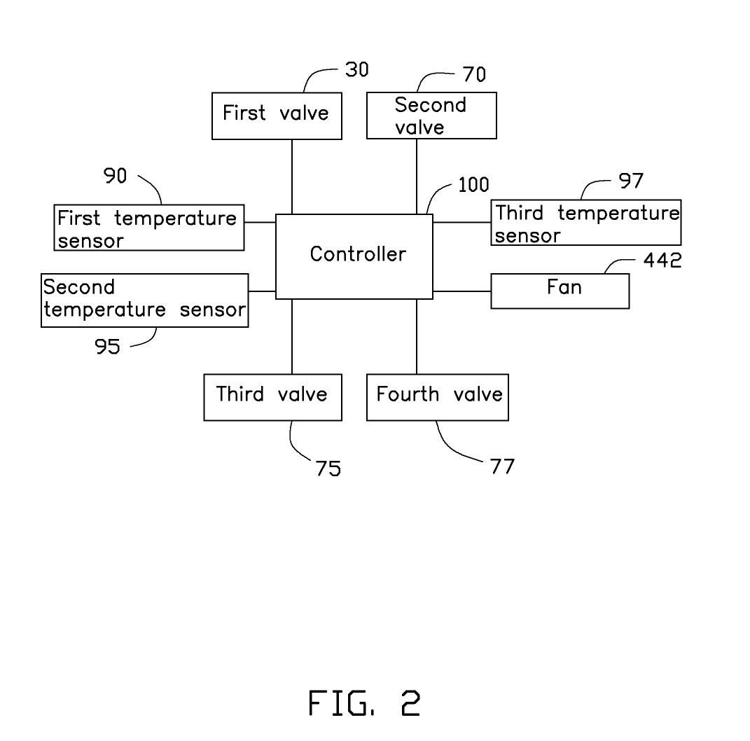

FIG. 2 is a block diagram of the heat dissipation system. The first valve apparatus 30, the second valve apparatus 70, the third valve 75, the fourth valve 77, the first temperature sensor 90, a second temperature sensor 95, the third temperature sensor 97, and the fans 442 and 542 are all electrically coupled to the controller 10. According to temperature sensed by the first temperature sensor 90, a second temperature sensor 95, and the third temperature sensor 97, the controller 10 can control the first end 31 of the first valve apparatus 30 to be connected to the second end 32 or the third end 33, control the first end 71 of the second valve apparatus 70 to be connected to the second end 72 or the third end 73, and control the third valve 75 and the fourth valve 77 to turn on or turn off, thereby controlling the flow of the liquid flowing through the heat dissipation system.

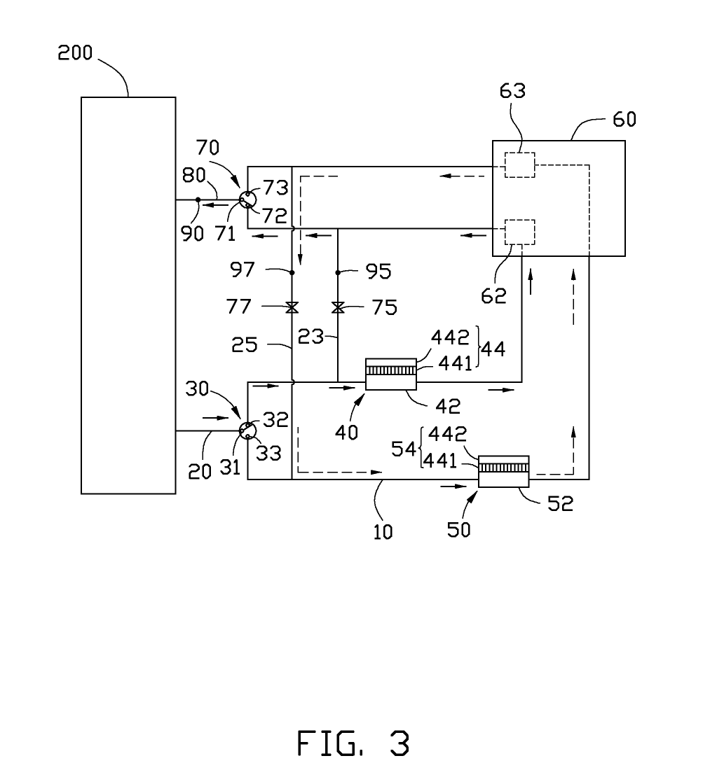

FIG. 3 shows the heat dissipation system in a first state of use. The liquid cooling cabinet server 200 operates to generate a high heat. The controller 10 controls the first end 31 of the first valve apparatus 30 to be connected to the second end 32, controls the first end 71 of the second valve apparatus 70 to be connected to the second end 72, controls the third valve 75 to turn off, and controls the fourth valve 77 to turn on. The cooling liquid of the first water tank 42 flows through the first pump 62, the second end 72 of the second valve apparatus 70, the first end 71 of the second valve apparatus 70, the inlet pipe 80, and the first temperature sensor 90, to enter the cabinet server 200 through the inlet 203. The heat of the cabinet server 200 is transferred to the cooling liquid. Thus, the cooling liquid is heated. The heated cooling liquid flows back into the first water tank 42 through the outlet 201, the outlet pipe 20, the first end 31 of the first valve apparatus 30, and the second end 32 of the first valve apparatus 30. The heat of the heated cooling liquid in the first water tank 42 is transferred to the heat sink 441, and the fan 442 dissipates the heat from the heat sink 441. In the same time, the cooling liquid of the second water tank 52 flows through the second pump 63, the second branch pipe 25, the third temperature sensor 97, and the fourth valve 77, to flow back into the second water tank 52. The heat of the cooling liquid of the second water tank 52 is transferred to the heat sink 541, and the fan 542 dissipates the heat from the heat sink 541. Thus, the cooling liquid of the second water tank 52 is cooled. The third temperature sensor 97 outputs a signal to the controller 100 when the temperature of the cooling liquid of the second branch pipe 25 is less than a predetermined value, to allow the controller 100 to control the fourth valve 77 and the fan 542 to turn off.

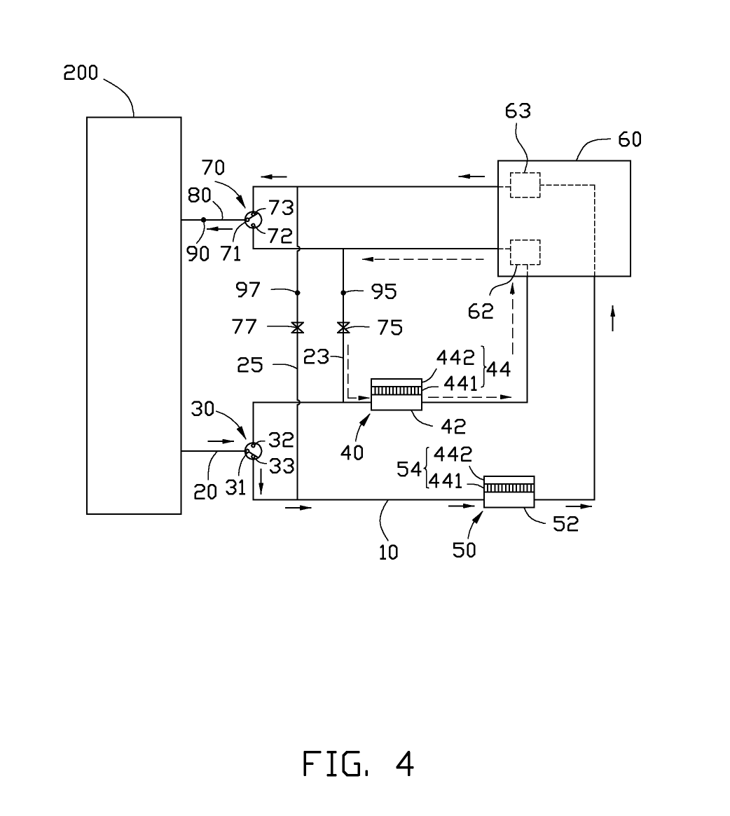

FIG. 4 shows the heat dissipation system in a second state of use. The first temperature sensor 90 outputs a signal to the controller 100 when the temperature of the cooling liquid of the inlet pipe 80 is greater than the predetermined value, to allow the controller 100 to control the first end 31 of the first valve apparatus 30 to be connected to the third end 33, control the first end 71 of the second valve apparatus 70 to be connected to the third end 73, control the fourth valve 77 to turn off, and control the third valve 75 to turn on. The cooled cooling liquid of the second water tank 52 flows through the second pump 63, the third end 73 of the second valve apparatus 70, the first end 71 of the second valve apparatus 70, the inlet pipe 80, and the first temperature sensor 90, to enter the cabinet server 200 through the inlet 203. The heat of the cabinet server 200 is transferred to the cooled cooling liquid. Thus, the cooled cooling liquid is heated. The heated cooling liquid flows back into the second water tank 52 through the outlet 201, the first end 31 of the first valve apparatus 30, and the third end 33 of the first valve apparatus 30. The heat of the heated cooling liquid in the second water tank 52 is transferred to the heat sink 541, and the fan 542 dissipates the heat from the heat sink 541. In the same time, the heated cooling liquid of the first water tank 42 flows through the first pump 62, the first branch pipe 23, the second temperature sensor 95, and the third valve 75, to flow back into the first water tank 42. The heat of the heated cooling liquid of the first water tank 42 is transferred to the heat sink 441, and the fan 442 dissipates the heat from the heat sink 441. Thus, the heated cooling liquid of the first water tank 42 is cooled. The second temperature sensor 95 outputs a signal to the controller 100 when the temperature of the cooled cooling liquid of the first branch pipe 23 is less than a predetermined value, to allow the controller 100 to control the third valve 75 and the fan 442 to turn off.

The first temperature sensor 90 outputs a signal to the controller 100 when the temperature of the cooling liquid of the inlet pipe 80 is greater than the predetermined value, to allow the controller 100 to control the first end 31 of the first valve apparatus 30 to be connected to the second end 32, control the first end 71 of the second valve apparatus 70 to be connected to the second end 72, control the third valve 75 to turn off, and control the fourth valve 77 to turn on. Thus, the first heat dissipation apparatus 40 dissipates the cabinet server 200 again. The controller 100 can control the first heat dissipation apparatus 40 to dissipate the cabinet server 200 or control the second dissipation apparatus 50 to dissipate the cabinet server 200.

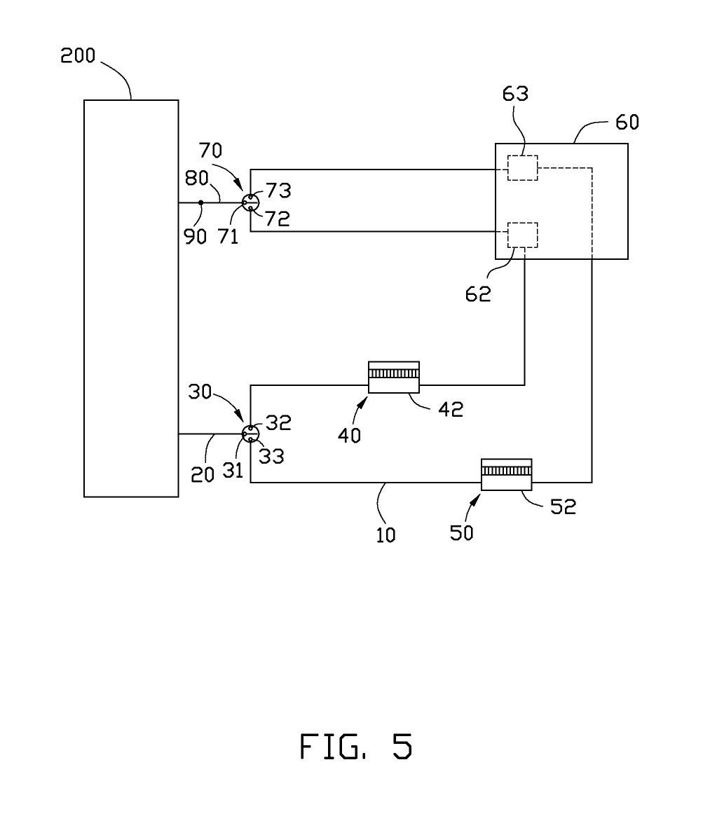

FIG. 5 shows a second embodiment of a heat dissipation system substantially similar to the first embodiment of the heat dissipation system, except that the heat dissipation system of the second embodiment omits the first branch pipe 23, the second temperature sensor 95, the third valve 75, the second branch pipe 25, the third temperature sensor 97, and the fourth valve 77. The controller 100 controls the first end 31 of the first valve apparatus 30 to be connected to the second end 32, and the first end 71 of the second valve apparatus 70 to be connected to the second end 72, to allow the first heat dissipation apparatus 40 to dissipate the cabinet server 200, or controls the first end 31 of the first valve apparatus 30 to be connected to the third end 33, and the first end 71 of the second valve apparatus 70 to be connected to the third end 73, to allow the second heat dissipation apparatus 50 to dissipate the cabinet server 200.

In the another embodiment, the first valve apparatus 30 can be replaced by two gate gurgle valves. One of the gate gurgle valves is installed to a point of the connecting pipe 10 between the first heat dissipation apparatus 40 and the outlet pipe 20, and the other gate gurgle valves is installed to a point of the connecting pipe 10 between the second heat dissipation apparatus 50 and the outlet pipe 20. The two gate gurgle valves are electrically coupled to the controller 100. The controller 100 controls the two gate gurgle valves to turn on or turn off.

It is to be understood, that even though numerous characteristics and advantages of the embodiment have been set forth in the foregoing description, together with details of the structure and function of the embodiment, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A heat dissipation system for cooling a cabinet server with an outlet and an inlet, the heat dissipation system comprising:
an outlet pipe to be connected to the outlet of the cabinet server;
an inlet pipe to be connected to the inlet of the cabinet server;
a pump apparatus located between the outlet pipe and the inlet pipe;
a first heat dissipation apparatus and a second heat dissipation apparatus connected between the outlet pipe and the pump apparatus in parallel; and
a first valve apparatus comprising a first end connected to the outlet pipe, a second end connected to the first heat dissipation apparatus, and a third end connected to the second heat dissipation apparatus;
wherein the first end of the first valve apparatus is operable to be connected to either the second end or the third end.

2. The heat dissipation system of claim 1, wherein the first valve apparatus is a three way valve.

3. The heat dissipation system of claim 2, wherein the pump apparatus comprises a first pump connected to the first heat dissipation apparatus, and a second pump connected to the second heat dissipation apparatus.

4. The heat dissipation system of claim 3, wherein the first heat dissipation apparatus comprises a first water tank connected between the second end of the first valve apparatus and the first pump.

5. The heat dissipation system of claim 4, wherein the first heat dissipation apparatus further comprises a heat sink attached to the first water tank and a fan installed to the heat sink.

6. The heat dissipation system of claim 3, wherein the second heat dissipation apparatus comprises a second water tank connected between the third end of the first valve apparatus and the second pump.

7. The heat dissipation system of claim 6, wherein the second heat dissipation apparatus further comprises a heat sink attached to the second water tank and a fan installed to the heat sink.

8. The heat dissipation system of claim 3, further comprising a second valve apparatus, wherein the second valve comprises a first end connected to the inlet pipe, a second end connected to the first pump, and a third end connected to the second pump.

9. The heat dissipation system of claim 8, wherein the second valve apparatus is a three way valve.

10. The heat dissipation system of claim 8, further comprising a controller and a first temperature sensor installed to the inlet pipe, wherein the first valve apparatus, the second valve apparatus, and the first temperature sensor are electrically coupled to the controller, according to temperature sensed by the first temperature sensor, the controller controls the first ends of the first valve apparatus and the second valve apparatus to be connected to the second ends or the third ends, to control the first heat dissipation apparatus to dissipate the cabinet server, or the second heat dissipation apparatus to dissipate the cabinet server.

11. The heat dissipation system of claim 10, further comprising a first branch pipe and a third valve, wherein an end of the first branch pipe is connected between the second end of the second valve apparatus and the first pump, and an opposite end of the first branch pipe is connected between the second end of the first valve apparatus and the first heat dissipation apparatus, the third valve is installed on the first branch, cooling liquid of the first water tank flows through the first pump and the third valve, to flow back into the first water tank.

12. The heat dissipation system of claim 11, further comprising a second temperature sensor installed to the first branch pipe, wherein the second temperature sensor and the third valve are electrically coupled to the controller, according to temperature sensed by the second temperature sensor, the controller controls the third valve, the fan of the first heat dissipation apparatus, and the first pump to turn on or turn off.

13. The heat dissipation system of claim 10, further comprising a second branch pipe and a fourth valve, wherein an end of the second branch pipe is connected between the third end of the second valve apparatus and the second pump, and an opposite end of the second branch pipe is connected between the third end of the first valve apparatus and the second heat dissipation apparatus, the fourth valve is installed on the second branch pipe, cooling liquid of the second water flows through the second pump and the fourth valve, to flow back into the second water tank.

14. The heat dissipation system of claim 13, further comprising a third temperature sensor installed to the second branch pipe, wherein the third temperature and the fourth valve are electrically coupled to the controller, according to temperature sensed by the third temperature sensor, the controller controls the fourth valve, the fan of the second heat dissipation apparatus, and the second pump to turn on or turn off.
